(19) United States
(12) Patent Application Publication
(10) Pub. No.: US 2026/0371606 A1
(43) Pub. Date: Nov. 19, 2026

(54) ELECTRONIC DEVICE AND METHOD FOR FABRICATING THE SAME

(71) Applicant: SK hynix Inc., Gyeonggi-do (KR)

(72) Inventors: Keo Rock CHOI, Gyeonggi-do (KR); Jong Min YUN, Gyeonggi-do (KR)

(21) Appl. No.: 19/405,432

(22) Filed: Dec. 2, 2025

(30) Foreign Application Priority Data
May 19, 2025 (KR) 10-2025-0064409

(51) Int. Cl. H10B 61/00; H10N 50/01; H10N 50/10; H10N 50/80

(52) U.S. Cl. CPC H10B 61/10; H10N 50/01; H10N 50/10; H10N 50/80

(57) ABSTRACT

Disclosed are a semiconductor device and a method for fabricating the same. The semiconductor device includes a variable resistance memory layer including a plurality of magnetic tunnel junction (MTJ) layers, and a first capping layer, including beryllium oxide, formed covering an upper surface and sidewalls of the plurality of MTJ layers. Each MTJ layer includes a fixed layer having a fixed magnetization direction, a free layer having a changeable magnetization direction, and a tunnel barrier layer disposed between the fixed layer and the free layer.

### CROSS-REFERENCE TO RELATED APPLICATIONS

The present application claims priority under 35 U.S.C 119(a) to Korean Patent Application No. 10-2025-0064409, filed on May 19, 2025, which is incorporated herein by reference in its entirety.

### BACKGROUND

### 1. Field

Various embodiments of the present disclosure relate to a semiconductor device, and more particularly, to a semiconductor device including a magnetic tunnel junction structure, and a method for fabricating the same.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices, and researchers and the industry are studying to develop such semiconductor devices. The semiconductor devices include those capable of storing data by taking advantage of the characteristics of switching between different resistance states according to the applied voltage or current, for example, a Resistive Random Access Memory (RRAM), a Phase-change Random Access Memory (PRAM), a Ferroelectric Random Access Memory (FRAM), a Magneto-resistive Random Access Memory (MRAM), an e-fuse and the like.

### SUMMARY

Embodiments of the present disclosure are directed to a magnetic tunnel junction (MTJ) device, capable of improving the deterioration of thermal stability (Δ) that may be caused by the heat generated during an operation of the MTJ device and a decrease of the critical switching current (I_{c}) that may be caused from the deterioration of thermal stability (Δ) by applying beryllium oxide (BeO) having a high thermal conductivity as a material for a capping layer of the MTJ device, and a method for fabricating the same.

In accordance with an embodiment of the present disclosure, a semiconductor device includes a variable resistance memory layer including a plurality of magnetic tunnel junction (MTJ) layers, and a first capping layer, including beryllium oxide, formed covering an upper surface and sidewalls of the plurality of MTJ layers. Each MTJ layer includes a fixed layer having a fixed magnetization direction, a free layer having a changeable magnetization direction, and a tunnel barrier layer disposed between the fixed layer and the free layer.

In accordance with another embodiment of the present disclosure, a method for fabricating a semiconductor device includes: forming, over a substrate, a magnetic tunnel junction (MTJ) layer including a fixed layer having a fixed magnetization direction, a free layer having a changeable magnetization direction, and a tunnel barrier layer interposed between the fixed layer and the free layer; forming an MTJ pattern by patterning the MTJ layer using a hard mask layer as an etching barrier; and forming a first capping layer, including beryllium oxide, covering an upper surface and sidewalls of the MTJ pattern.

### BRIEF DESCRIPTION OF THE DRAWINGS

FIG. 1 is a graph illustrating the thermal conductivities of diverse materials including beryllium oxide.

FIG. 2 is a cross-sectional view illustrating a semiconductor device in accordance with an embodiment of the present disclosure.

FIG. 3 is a cross-sectional view illustrating a semiconductor device in accordance with another embodiment of the present disclosure.

FIG. 4 is a cross-sectional view illustrating a semiconductor device in accordance with another embodiment of the present disclosure.

FIG. 5 is a cross-sectional view illustrating a semiconductor device in accordance with another embodiment of the present disclosure.

FIG. 6 is a cross-sectional view illustrating a semiconductor device in accordance with another embodiment of the present disclosure.

FIGS. 7A-7E are cross-sectional views illustrating a semiconductor device and a method for fabricating the same in accordance with an embodiment of the present disclosure.

### DETAILED DESCRIPTION

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

A variable resistance element refers to an element that may switch between different resistance states according to the voltage or current applied to both ends of the variable resistance element. According to the resistance state of the variable resistance element, different data may be stored in the variable resistance element. In other words, the variable resistance element may function as a memory cell.

A plurality of such variable resistance elements may be integrated and arranged, and a variable resistance memory layer formed of these variable resistance elements may be one among the core constituent elements of a semiconductor memory that performs a data storing function. The variable resistance memory layer may form a memory cell together with a select element, and the select element may be electrically connected to the variable resistance element and control the access. The memory cells formed in this manner may be arranged in various ways to form a semiconductor memory array.

In particular, the variable resistance element may include a magnetic tunnel junction (MTJ) structure including a free layer having a changeable magnetization direction, a fixed layer having a fixed magnetization direction, and a tunnel barrier layer interposed between the free layer and the fixed layer. In the variable resistance elements, the magnetization direction of the free layer may change according to the applied voltage or current to become parallel or antiparallel to the magnetization direction of the fixed layer, and accordingly, the variable resistance element may switch between a low resistance state or a high resistance state.

The embodiments of the present disclosure described below provide a semiconductor device having an improved structure that may satisfy or improve diverse properties required for a variable resistance element and a variable resistance memory layer, and a method for fabricating the semiconductor device.

In an MTJ-based variable resistance element, which is a memory element of a Magneto-resistive Random Access Memory (MRAM), heat may be generated as the current is applied to the free layer during an operation, which deteriorates the thermal stability (Δ) of the free layer and decreases the critical switching current (I_{c}). When the thermal stability (Δ) is deteriorated and the critical switching current (I_{c}) is decreased, unintentional magnetization reversal may occur even with a low current during a read operation, which may cause a concern of reliability, such as read interference.

To solve this concern, a technology that may quickly release the heat generated during an operation to the outside and prevent deterioration of the thermal stability (Δ) by applying a material with a high thermal conductivity to the capping layer that covers the upper surface and sidewalls of the MTJ-based variable resistance element (or device)_ is attracting attention.

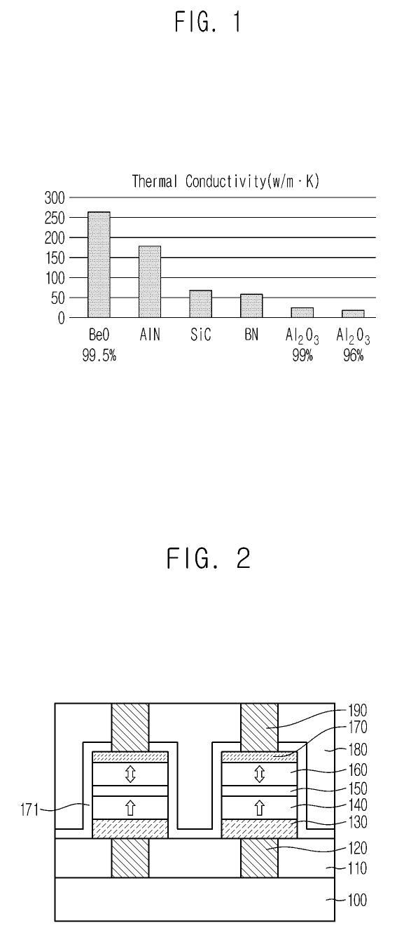

FIG. 1 is a graph comparing the thermal conductivities of diverse dielectric materials. According to the graph, aluminum oxide (Al₂O₃), which is a typical material for the capping layer, may have a thermal conductivity of only approximately 20 watts per meter-kelvin (W/m·K) (Al₂O₃ 96%) to 25 W/m·K (Al₂O₃ 99%) according to the purity, while silicon carbide (SiC) and boron nitride (BN) have thermal conductivities of approximately 70 W/m·K and 60 W/m·K, respectively. Aluminum Nitride (AlN) may have a relatively high thermal conductivity of approximately 180 W/m·K, but beryllium oxide (BeO), which is of interest in the present disclosure, may exhibit a particularly high thermal conductivity (for example, indicating efficient heat transfer capabilities) of approximately 265 W/m·K when the purity is approximately 99.5% or higher.

Accordingly, the present disclosure provides a semiconductor device and a method for fabricating the same that may simultaneously stabilize the thermal stability (Δ) and the critical switching current (I_{c}) of the MTJ by applying beryllium oxide as a material for the capping layer of the MTJ to thereby effectively release the heat generated during an operation to the outside, and prevent a read operation from being interfered.

FIGS. 2-6 are cross-sectional views illustrating a semiconductor device in accordance with an embodiment of the present disclosure. FIGS. 2-6 illustrate a semiconductor device that forms a Spin Transfer Torque Magneto-resistive Random Access Memory (STT-MRAM).

Referring to FIG. 2, the MTJ device of the semiconductor device in accordance with the embodiment of the present disclosure may include a first electrode layer 130, a fixed layer 140, a tunnel barrier layer 150, a free layer 160, and a second electrode layer 170.

The fixed layer 140 may have a fixed magnetization direction. For example, the magnetization direction of the fixed layer 140 may be fixed regardless of the program current passing through the fixed layer 140.

The fixed layer 140 may include a ferromagnetic substance. For example, the fixed layer 140 may include at least one among an amorphous rare earth element alloy, a multi-layer thin layer in which ferromagnetic metals (FM) and nonmagnetic metals (NM) are alternately stacked, an alloy having an L10-type crystal structure, a cobalt-based alloy, and a combination thereof, but the concept and spirit of the present disclosure are not limited thereto.

The amorphous rare earth element alloy may include, for example, alloys such as terbium-iron (TbFe), terbium-cobalt (TbCo), terbium-iron-cobalt (TbFeCo), dysprosium-terbium-iron-cobalt (DyTbFeCo), gadolinium-terbium-cobalt (GdTbCo) and the like. The multi-layer thin layer in which the magnetic metals and the non-magnetic metals are alternately stacked may include, for example, cobalt/platinum (Co/Pt), cobalt/palladium (Co/Pd), cobalt-chromium/platinum (CoCr/Pt), cobalt/ruthenium (Co/Ru), cobalt/osmium (Co/Os), cobalt/gold (Co/Au), nickel/copper (Ni/Cu) and the like. The alloy having the L10-type crystal structure may include, for example, alloys such as Fe₅₀Pt₅₀, Fe₅₀Pd₅₀, Co₅₀Pt₅₀, Fe₃₀Ni₂₀Pt₅₀, Co₃₀Ni₂₀Pt₅₀ and the like. The cobalt-based alloy may include, for example, alloys such as cobalt-chromium (CoCr), cobalt-platinum (CoPt), cobalt-chromium-platinum (CoCrPt), cobalt-chromium-tantalum (CoCrTa), cobalt-chromium-platinum-tantalum (CoCrPtTa), cobalt-chromium-niobium (CoCrNb), cobalt-iron-boron (CoFeB) and the like. For example, the fixed layer 140 is described below as including CoFeB.

According to some embodiments of the present disclosure, the fixed layer 140 may have a perpendicular magnetic anisotropy (PMA). In other words, the fixed layer 140 may have a magnetization easy axis in a direction perpendicular to the direction that the fixed layer 140 extends. The unidirectional arrow in the fixed layer 140 may indicate that the magnetization direction of the fixed layer 140 is fixed vertically.

The free layer 160 may have a changeable magnetization direction. For example, the magnetization direction of the free layer 160 may be variable according to the program current passing through the free layer 160. According to some embodiments of the present disclosure, the magnetization direction of the free layer 160 may be changed by a spin transfer torque (STT).

The free layer 160 may include at least one magnetic element. The magnetic element, for example, may include at least one among iron (Fe), nickel (Ni), and cobalt (Co), but the concept and spirit of the present disclosure are not limited thereto.

According to some embodiments of the present disclosure, the free layer 160 may have a perpendicular magnetic anisotropy (PMA). In other words, the free layer 160 may have a magnetization easy axis in a direction perpendicular to the direction that the free layer 160 extends. The bidirectional arrows in the free layer 160 may indicate that the magnetization direction of the free layer 160 may be magnetized parallel to or antiparallel to the magnetization direction of the fixed layer 140.

According to some embodiments of the present disclosure, the free layer 160 may include a magnetic element that may induce an interfacial perpendicular magnetic anisotropy (i-PMA) by being bonded with oxygen. The magnetic element may be, for example, iron (Fe). For example, the free layer 160 may be described below as including CoFe or CoFeB.

According to some embodiments of the present disclosure, the free layer 160 may have a crystal structure. For example, at least a portion of the free layer 160 may have a body-centered cubic (BCC) crystal structure.

The tunnel barrier layer 150 may be interposed between the fixed layer 140 and the free layer 160. The tunnel barrier layer 150 may function as a tunnel barrier that causes a quantum mechanical tunneling between the fixed layer 140 and the free layer 160.

The tunnel barrier layer 150 may include, for example, at least one among magnesium oxide (MgO), aluminum oxide (Al₂O₃), silicon oxide (SiO₂), tantalum oxide (Ta₂O₅), silicon nitride (SiN), aluminum nitride (AlN), and combinations thereof, but the concept and spirit of the present disclosure are not limited thereto. For example, the tunnel barrier layer 150 may be described below as including magnesium oxide having a face-centered cubic (FCC) crystal structure or a sodium chloride (NaCl) crystal structure.

The MTJ device including the fixed layer 140, the tunnel barrier layer 150, and the free layer 160 may function as a variable resistance element that may switch between two resistance states according to the electrical signal applied thereto, for example, a program current. For example, when the magnetization direction of the fixed layer 140 and the magnetization direction of the free layer 160 are parallel to each other, the MTJ device may have a low resistance value and may store this as data ‘0’. Conversely, when the magnetization direction of the fixed layer 140 and the magnetization direction of the free layer 160 are antiparallel to each other, the MTJ device may have a high resistance value and may store this resistance value as data ‘1’.

According to the embodiment of the present disclosure, the fixed layer 140, the tunnel barrier layer 150, and the free layer 160 may be sequentially stacked over a substrate 100. The substrate 100 may be, for example, a silicon substrate, a gallium arsenide substrate, a silicon germanium substrate, a ceramic substrate, a quartz substrate, or a glass substrate for a display, or the substrate 100 may be a Semiconductor-On-Insulator (SOI) substrate, but the concept and spirit of the present disclosure are not limited thereto.

The MTJ device of the semiconductor device in accordance with the embodiment of the present disclosure may be coupled to the substrate 100 and a conductive line (not shown). For example, a first inter-layer dielectric layer 110 may be formed over the substrate 100. The first electrode layer 130, the fixed layer 140, the tunnel barrier layer 150, the free layer 160, and the second electrode layer 170 may be sequentially stacked over the first inter-layer dielectric layer 110.

A first capping layer 171 may be formed to cover the MTJ layer, that is, the sidewalls of the first electrode layer 130, the fixed layer 140, the tunnel barrier layer 150, the free layer 160, and the second electrode layer 170 and the upper surface of the second electrode layer 170.

The first capping layer 171 may be formed of a dielectric layer including beryllium oxide (BeO). beryllium oxide (BeO) may be a material having a very high thermal conductivity of approximately 100 W/m·K to 300 W/m·K, reaching approximately 265 W/m·K. This is a significantly higher value compared to not only silicon oxide (SiO₂) having a thermal conductivity of approximately 1.4 W/m·K, which is generally used in semiconductor processes, but also aluminum oxide (Al₂O₃) having a thermal conductivity of approximately 20 to 25 W/m·K, or silicon carbide (SiC) and boron nitride (BN) having thermal conductivities of approximately 70 W/m·K and 60 W/m·K, which is clearly shown in the graph of FIG. 1 in accordance with the present disclosure comparing the thermal conductivities.

According to one embodiment of the present disclosure, the first capping layer 171 may be formed in a thickness range of approximately 1 nm to 20 nm. Within this range, the first capping layer 171 may exhibit sufficient thermal conductivity and may cope with the demands for high integration and miniaturization of the MTJ structure.

When the thickness is less than approximately 1 nm, the first capping layer 171 may be physically too thin to effectively release the heat generated during an operation of the device, so the heat release effect may be decreased, and the protection function of the first capping layer 171, such as prevention of oxidation or interface stabilization, may also be decreased. On the contrary, when the thickness exceeds approximately 20 nm, the stacking thickness of the entire device may be increased in a manner that deteriorates the integration degree of the device, and unfavorable factors in the process, such as an increase in a thin layer stress and an instable etching process may be caused. Therefore, the thickness range of approximately 1 nm to 20 nm may be the optimal range obtained in consideration of all of the thermal conductivity, mechanical stability, interface adhesion, and process compatibility for functioning as a capping layer.

To be more specific, the first capping layer 171 may be formed to have a thickness of approximately 3 nm to 10 nm. The first capping layer 171 having the thickness within this range may be favorable for securing the thickness uniformity of a thin layer while maximizing the characteristics of a material having a high thermal conductivity such as beryllium oxide (BeO), and it may also satisfy the requirement of the minimum thickness suitable for a high-integration semiconductor fabrication process.

Based on the thermal conductivity characteristics (of material included in the first capping layer 171), the first capping layer 171 including beryllium oxide (BeO) may effectively release the heat generated during the operation of the MTJ device to the outside, thereby preventing thermal instability of the free layer 160 that may occur due to the accumulation of heat, and thus improving the thermal stability (Δ). Also, since the phenomenon of deterioration of the critical switching current (I_{c}) may be minimized, the disclosed embodiments may effectively suppress the read interference phenomenon in which unintentional magnetization reversal occurs even at a low read current.

As a result, by utilizing beryllium oxide (BeO) as a material for the capping layer, the operational reliability and data retention property of the MTJ device may be improved, which is very advantageous in satisfying the high heat resistance and high stability required in diverse magneto-resistive memory devices including an STT-MRAM. Therefore, beryllium oxide (BeO) may be selected among the optimal materials that provide the most advantageous property as a material for the capping layer in terms of securing the thermal stability and maintaining the critical switching current (I_{c}).

The first capping layer 171 may be formed in an amorphous or crystalline form. The first capping layer 171 may be realized in a multi-layer structure or a mixed layer form along with materials such as aluminum nitride (AlN), zirconium oxide (ZrO₂), and silicon oxide (SiO₂) in addition to beryllium oxide, as needed. This structural diversity provided by the disclosed embodiments may enable design of the optimal capping layer in consideration of oxidation resistance, insulation property, process stability and the like in addition to the thermal conductivity.

The first capping layer 171 of the present disclosure may include beryllium oxide (BeO) of an amorphous or crystalline form according to the formation method and process conditions, and different advantages may be provided according to each structure.

Amorphous beryllium oxide (BeO) may be of an amorphous state without a crystal lattice and may have the advantages of minimized surface roughness (Ra) and excellent thickness uniformity when a thin layer is formed. This may improve the interface quality when a fine structure of an MTJ device is formed, and may be advantageous in terms of selectivity control and process flexibility in an etching process. In particular, it may suppress horizontal/vertical diffusion of a layer in a complex three-dimensional structure or a highly integrated device and may improve the capability of preventing electrical leakage.

Crystalline beryllium oxide (BeO) may be formed based on a crystal structure with a specific orientation, and may realize a higher thermal conductivity than that of an amorphous structure. Since beryllium oxide (BeO) in a crystalline state has a decreased thermal resistance between the crystal grains, it may be able to release the heat generated during the operation of the MTJ device to the outside more effectively. This may make it possible to further stabilize the thermal stability (Δ) of the free layer 160 and may be more advantageous for preventing a read operation from being interfered by minimizing the deterioration of the critical switching current (I_{c}). Also, since the crystalline beryllium oxide (BeO) has excellent heat resistance, the physical properties may be maintained stably even in a subsequent annealing process or a high-temperature process.

Therefore, what to select between the amorphous beryllium oxide (BeO) and the crystalline beryllium oxide (BeO) for the first capping layer 171 may be flexibly determined according to the design requirements, process conditions, and target performance of the device, and each form may contribute to improving the performance of heat release and interface quality of the MTJ device, thereby effectively realizing the technical effects of the present disclosure.

A second inter-layer dielectric layer 180 may be formed over the first inter-layer dielectric layer 110. The second inter-layer dielectric layer 180 may cover the first capping layer 171 and the second electrode contact 190. Each of the first inter-layer dielectric layer 110 and the second inter-layer dielectric layer 180 may include a dielectric material, such as silicon oxide or silicon oxynitride, but the concept and spirit of the present disclosure are not limited thereto.

According to some embodiments of the present disclosure, a first electrode contact 120 may be formed between the MTJ device, for example, the first electrode layer 130, and the substrate 100. The first electrode contact 120 may penetrate the first inter-layer dielectric layer 110 to be coupled to the substrate 100. The first electrode contact 120 may include at least one among, for example, a doped semiconductor material, such as doped silicon, a metal, such as tungsten, aluminum, copper, titanium, and/or tantalum, a conductive metal nitride, such as titanium nitride, tantalum nitride, and/or tungsten nitride, and a metal-semiconductor compound, such as a metal silicide, but the concept and spirit of the present disclosure are not limited thereto.

According to some embodiments of the present disclosure, the first electrode layer 130 may be formed over the first inter-layer dielectric layer 110. For example, the first electrode layer 130 may cover a lower surface of the fixed layer 140. The first electrode layer 130 may be coupled to the first electrode contact 120. Accordingly, the MTJ device, for example, the fixed layer 140, may be coupled to the substrate 100 and/or a lower interconnection through the first electrode layer 130 and/or the first electrode contact 120.

The first electrode layer 130 may include, for example, a conductive metal nitride or a metal. According to some embodiments of the present disclosure, the first electrode layer 130 may function as a seed layer of the fixed layer 140. For example, when the fixed layer 140 is formed of a material having an L10-type crystal structure, the first electrode layer 130 may include a conductive metal nitride having a face-centered cubic crystal structure or a sodium chloride (NaCl) crystal structure, such as titanium nitride, tantalum nitride, chromium nitride, or vanadium nitride. Also, for example, when the fixed layer 140 has a close-packed hexagonal crystal structure, the first electrode layer 130 may include a conductive material having a close-packed hexagonal crystal structure, such as ruthenium. However, this is merely by way of example, and the first electrode layer 130 may also include a conductive material, such as titanium or tantalum.

According to an embodiment of the present disclosure, a second electrode contact 190 may be formed between the MTJ device, for example, the second electrode layer 170, and an upper interconnection (not shown). The second electrode contact 190 may penetrate the second inter-layer dielectric layer 180 to be coupled to the upper interconnection (not shown). The second electrode contact 190 may include at least one among a doped semiconductor material, for example, doped silicon, a metal, for example, tungsten, aluminum, copper, titanium, and/or tantalum, a conductive metal nitride, for example, titanium nitride, tantalum nitride, and/or tungsten nitride, and a metal-semiconductor compound, for example, a metal silicide, but the concept and spirit of the present disclosure are not limited to.

The second electrode layer 170 may be formed over the free layer 160. For example, the second electrode layer 170 may cover the upper surface of the free layer 160. The second electrode layer 170 may be coupled to the second electrode contact 190. Accordingly, the MTJ device, for example, the free layer 160, may be coupled to the upper interconnection through the second electrode layer 170 and/or the second electrode contact 190.

The second electrode layer 170 may include, for example, a conductive metal nitride or a metal. According to some embodiments of the present disclosure, the second electrode layer 170 may protect the free layer 160. For example, the second electrode layer 170 may include at least one among ruthenium (Ru), tantalum (Ta), and a nitride thereof.

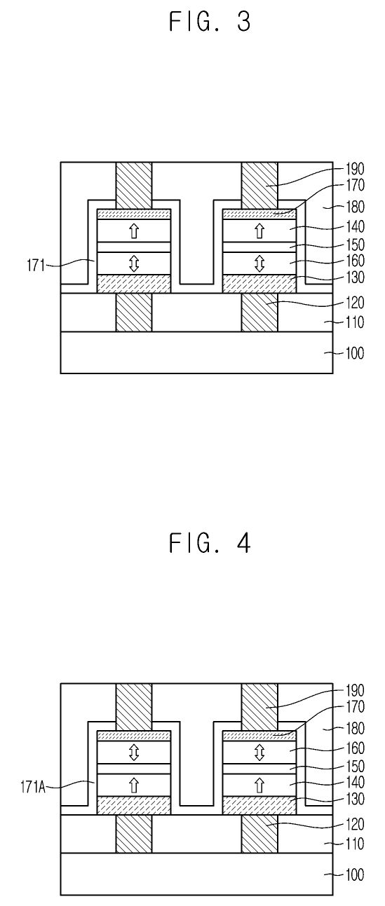

FIGS. 3-6 are cross-sectional views illustrating a semiconductor device in accordance with another embodiment of the present disclosure. For convenience, description on the portion also appearing in FIG. 2 may be briefly described or omitted.

FIG. 3 is a cross-sectional view illustrating a structure of an MTJ in accordance with another embodiment of the present disclosure. The embodiment of FIG. 2 includes a structure in which the fixed layer 140, the tunnel barrier layer 150, the free layer 160, and the second electrode layer 170 are sequentially stacked over the first electrode layer 130.

On the other hand, the embodiment of the present disclosure illustrated in FIG. 3 may have a structure in which the positions of the fixed layer 140 and the free layer 160 are switched with each other. In other words, the structure may include the free layer 160, the tunnel barrier layer 150, the fixed layer 140, and the second electrode layer 170 that are sequentially stacked over the first electrode layer 130.

This configuration of the embodiment of the present disclosure may be selected according to the overall magnetization direction setting method of the MTJ device, requirements of the fabricating process, or specific applications, and some properties such as the magnetization reversal, read/write direction, and magnetic field interference resistance may vary according to the positions of the free layer and the fixed layer.

Therefore, the present disclosure may include not only the structure illustrated in FIG. 2, but also the structure in which the stacking order of the free layer 160 and the fixed layer 140 is reversed as illustrated in FIG. 3, and the embodiments may also be included in the technical concept and spirit of the present disclosure.

Even in a structure in which the positions of the free layer 160 and the fixed layer 140 are switched as illustrated in the embodiment of the present disclosure, the capping layer 171 illustrated in FIG. 2 may be applied in the same manner. The capping layer 171 may also effectively release the heat generated during the operation of the MTJ device, and the effects intended by the present disclosure, such as improved thermal stability (Δ) and suppressing the deterioration of the critical switching current (I_{c}), may also be sufficiently realized.

FIG. 4 is a cross-sectional view illustrating a semiconductor device in accordance with another embodiment of the present disclosure. To be specific, FIG. 4 is a cross-sectional view illustrating an MTJ structure in accordance with yet another embodiment of the present disclosure, in which the first capping layer 171 illustrated in FIG. 2 is replaced with a mixed first capping layer 171A having a single-layer structure in which beryllium oxide and another dielectric material are mixed.

The mixed first capping layer 171A may be formed of a single layer in which beryllium oxide (BeO) is mixed with at least one among zirconium oxide (ZrO₂), aluminum nitride (AlN), silicon carbide (SiC), boron nitride (BN), magnesium oxide (MgO), and zinc oxide (ZnO). Each of these materials may have a high thermal conductivity and an insulation property, and when combined with beryllium oxide (BeO), it may maintain the excellent thermal conductivity with stable physical properties compared to a single beryllium oxide (BeO) layer.

The thermal conductivity of the mixed first capping layer 171A may be slightly lower than that of the single beryllium oxide (BeO) layer, which has a thermal conductivity of approximately 265 W/m·K, but it may acquire a thermal conductivity of approximately 200 W/m·K or more. Also, the mixed first capping layer 171A may have the advantage of improving specific process conditions, such as temperature, surface flatness, and resistance to mechanical stress.

For example, zirconium oxide (ZrO₂) may have a high insulation property and excellent heat resistance. When zirconium oxide (ZrO₂) is mixed with beryllium oxide (BeO), the disclosed embodiments may improve the mechanical strength and resistance to thermal shock of the mixed first capping layer 171A. Aluminum nitride (AlN) may be a material with a thermal conductivity of approximately 180 W/m·K. When aluminum nitride (AlN) is mixed with beryllium oxide (BeO), it may function as a dielectric layer with a low dielectric loss while maintaining the heat release function. Silicon carbide (SiC) may have excellent high-temperature stability and chemical resistance, and may complement the stability of beryllium oxide (BeO) during a high-temperature process and improve the device stability in an electromagnetic environment. Also, with a layered structure, boron nitride (BN) may have excellent thermal conductivity and insulation property, and it may be advantageous for preventing diffusion at the interface and improving the stability of the thin layer (e.g., the mixed first capping layer 171A). Magnesium oxide (MgO) may also be applied to the tunnel barrier layer 150 in the MTJ device, and it may have excellent crystallographic compatibility. When magnesium oxide (MgO) is combined with beryllium oxide (BeO), the interface quality of the magnesium oxide (MgO) may be further stabilized. Also, zinc oxide (ZnO) may be a material suitable for a low-temperature process, and zinc oxide (ZnO) may be able to complement the high-temperature deposition of beryllium oxide (BeO) and improve the thin layer uniformity.

This mixed first capping layer 171A may be equivalent or similar to the single beryllium oxide (BeO) layer in terms of the thermal conductivity. To be specific, the mixed first capping layer 171A may have a thermal conductivity of approximately 200 W/m·K or more. Also, other effects such as improved process stability, interface quality, mechanical reliability, and insulation property may be expected additionally.

Therefore, even when the mixed first capping layer 171A is applied in accordance with the embodiment of the present disclosure, as shown in the embodiment of FIG. 2 using the first capping layer 171, the heat generated during the operation of the MTJ device may be effectively released, thereby improving the thermal stability (Δ) of the free layer and realizing the same effect of preventing a read operation from being interfered (i.e., protecting the read operation from interference) by suppressing the deterioration of the critical switching current (I_{c}).

The mixed first capping layer 171A may be formed, for example, by cross-depositing or co-depositing the precursors of the dielectric materials together with the beryllium oxide precursor through an Atomic Layer Deposition (ALD) process. The mixed first capping layer 171A formed as above may provide improved reliability in terms of not only the heat release property but also process conditions and layer quality uniformity compared to the capping layer based on a single material.

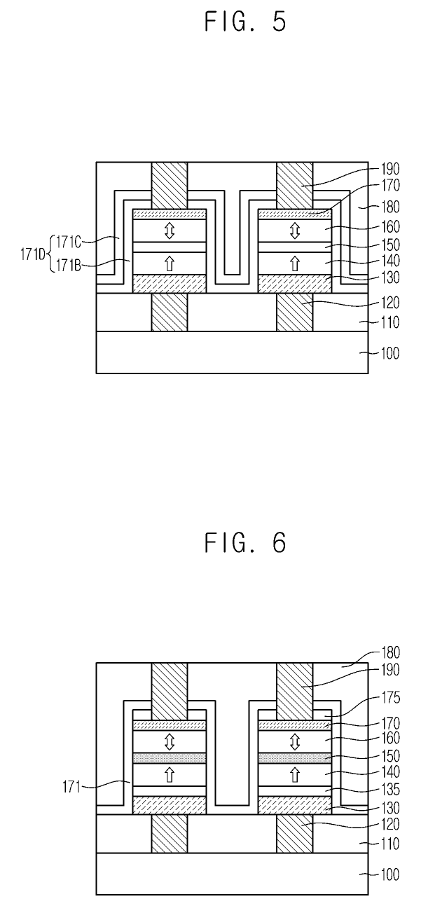

FIG. 5 is a cross-sectional view illustrating a semiconductor device in accordance with another embodiment of the present disclosure. To be specific, FIG. 5 illustrates an MTJ structure in accordance with yet another embodiment of the present disclosure, in which the first capping layer 171 of the single-layer structure illustrated in FIG. 2 is replaced with a first capping layer 171D of a multi-layer structure.

To be more specific, the first capping layer 171D may be of a multi-layer structure that is formed of a first lower capping layer 171B including beryllium oxide formed in the lower portion, and a first upper capping layer 171C including another dielectric material layer formed in the upper portion.

The first lower capping layer 171B may be formed of beryllium oxide (BeO) having a high thermal conductivity, and may realize the same technical effects as that of FIG. 2, such as improving the thermal stability (Δ) of the free layer by rapidly releasing the heat generated during the operation of the MTJ device to the outside, and preventing a read operation from being interfered by suppressing deterioration of the critical switching current (I_{c}).

The first upper capping layer 171C stacked in the upper portion may be formed of aluminum nitride (AlN), silicon oxide (SiO₂), silicon carbide (SiC), boron nitride (BN), aluminum oxide (Al₂O₃) and the like, and may provide heat resistance, oxidation resistance, interface protection, dielectric stability and the like.

Such a combination of the materials may have different physical properties and thus provide the following technical advantages. Aluminum nitride (AlN) may have a high thermal conductivity of approximately 180 W/m·K and a low dielectric loss, which may lead to electrical stability. When aluminum nitride (AlN) is combined with beryllium oxide (BeO), the heat release property and insulation property may be balanced. Silicon oxide (SiO₂) may have a high process compatibility and excellent interface stability. When silicon oxide (SiO₂) is formed over beryllium oxide (BeO), the mechanical stability and interface insulation property of the entire capping layer may be improved. Silicon carbide (SiC) may have an excellent high-temperature stability and chemical resistance. When silicon carbide (SiC) is used with beryllium oxide (BeO), it may complement the thermal reliability and corrosion resistance. Boron nitride (BN) may have a high insulation property and excellent thin layer interface property due to the layered structure, which may contribute to suppressing the oxidation at the interface and improving the thin layer uniformity in a multi-layer structure with beryllium oxide (BeO). Aluminum oxide (Al₂O₃) may have excellent processability and strong oxidation resistance, so it may serve as an anti-oxidation layer or a passivation layer without damaging the thermal conductivity of beryllium oxide (BeO).

The first capping layer (for example, first capping layer 171D) of the multi-layer structure may secure the thermal stability (Δ) of the free layer by effectively releasing the heat generated during the operation of the MTJ device, prevent a read operation from being interfered by suppressing the deterioration of the critical switching current (I_{c}), and also exhibit excellent performance in terms of the process reliability and lifespan of the device.

When the first capping layer (for example, first capping layer 171D) is formed in a multi-layer structure, the positions of the first lower capping layer 171B including beryllium oxide and the first upper capping layer 171C including another dielectric material layer may not be necessarily fixed. The stacking order of the two layers may be freely changed according to the process conditions, device structure, heat release direction, or convenience in fabrication.

In other words, a structure in which the first upper capping layer 171C including a dielectric material layer is formed in the lower portion and the first lower capping layer 171B including beryllium oxide is formed over the first upper capping layer 171C may also be included in the technical concept and spirit of the present disclosure. In this instance, not only the same technical effect may be realized in the MTJ structure, but also more flexible design is possible by optimizing the physical properties according to the stacking order.

As described above, when the first capping layer 171D is formed in a multi-layer structure, while the excellent thermal conductivity and MTJ property stabilization effect provided by the single beryllium oxide (BeO) layer of FIG. 2 may be maintained as they are, layer uniformity, process adaptability, interface reliability, mechanical durability and the like may be improved further additionally. Therefore, this embodiment of the present disclosure may provide a structure that may simultaneously secure the heat release efficiency and the electrical stability and may be particularly advantageously applied to a high-reliability MTJ-based memory device.

FIG. 6 is a cross-sectional view illustrating a semiconductor device in accordance with another embodiment of the present disclosure. FIG. 6 illustrates an MTJ structure in accordance with yet another embodiment of the present disclosure. The MTJ structure may include a structure in which a seed layer 135 is added to the lower portion of the fixed layer 140 and a second capping layer 175 is added to the upper portion of the free layer 160 based on the structure illustrated in FIG. 2.

The seed layer 135 may be disposed to contact the lower surface of the fixed layer 140 and may be spaced apart from the tunnel barrier layer 150 with the fixed layer 140 interposed therebetween. The seed layer 135 may be used to control the crystal growth direction of the fixed layer 140 and induce the formation of magnetic anisotropy. The seed layer 135 may function as a seed layer of the fixed layer 140. For example, when the fixed layer 140 is formed of a material having an L10-type crystal structure, the seed layer 135 may include a conductive metal nitride having a face-centered cubic crystal structure or a sodium chloride (NaCl) crystal structure, such as titanium nitride, tantalum nitride, chromium nitride, or vanadium nitride.

For example, when the fixed layer 140 has a close-packed hexagonal crystal structure, the seed layer 135 may include a conductive material having a close-packed hexagonal crystal structure, such as ruthenium. The seed layer 135 may include, for example, one or more among tantalum (Ta), platinum (Pt), ruthenium (Ru), and magnesium oxide (MgO), and contribute to stabilizing the crystal quality and magnetic property of the MTJ stacked structure. The seed layer 135 may also be formed of a multi-layer thin layer in which different non-magnetic metals are stacked. For example, the seed layer 135 may include a first non-magnetic layer and a second non-magnetic layer that are sequentially stacked. The first non-magnetic layer may include tantalum (Ta), and the second non-magnetic layer may include platinum (Pt), but the concept and spirit of the present disclosure are not limited thereto.

The second capping layer 175 may be formed to cover the upper surface of the MTJ layer, for example, the free layer 160, and may be spaced apart from the tunnel barrier layer 150 with the free layer 160 interposed therebetween. The second capping layer 175 may include beryllium oxide (BeO), similar to the first capping layer 171. The second capping layer 175 may serve as a passivation layer for preventing the accumulation of the heat that may occur in the upper portion of the free layer 160, oxidation, interface damage and the like after the MTJ pattern is formed, and for additionally securing the magnetization stability of the free layer 160.

The second capping layer 175 may further include one or more among silicon oxide (SiO₂), silicon carbide (SiC), boron nitride (BN), and aluminum oxide (Al₂O₃) in addition to beryllium oxide (BeO) as needed, but the concept and spirit of the present disclosure are not limited thereto. The second capping layer 175 may additionally secure diverse auxiliary properties of the capping layer, such as the insulation property, oxidation resistance, and layer uniformity.

As described above, according to this embodiment of the present disclosure, even though the seed layer 135 and the second capping layer 175 are added, all the technical effects of FIG. 2, such as improving the thermal stability (Δ) of the free layer, preventing deterioration of the critical switching current (I_{c}), and suppressing a read operation from being interfered, may be realized as they are by effectively releasing the heat generated during an MTJ operation through the first capping layer 171 in the same manner as that of FIG. 2.

Furthermore, the additional constituent elements of the seed layer 135 and the second capping layer 175 may contribute to improving the long-term reliability of the magnetic, structural, and electrical characteristics of the device, which is more advantageous for realizing a high-performance MTJ-based memory device.

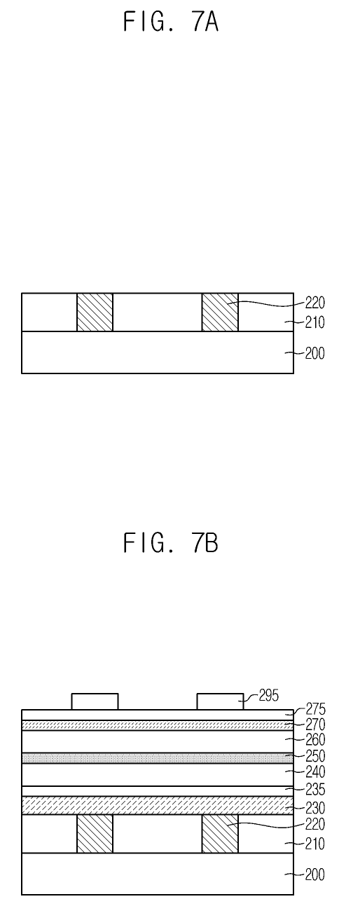

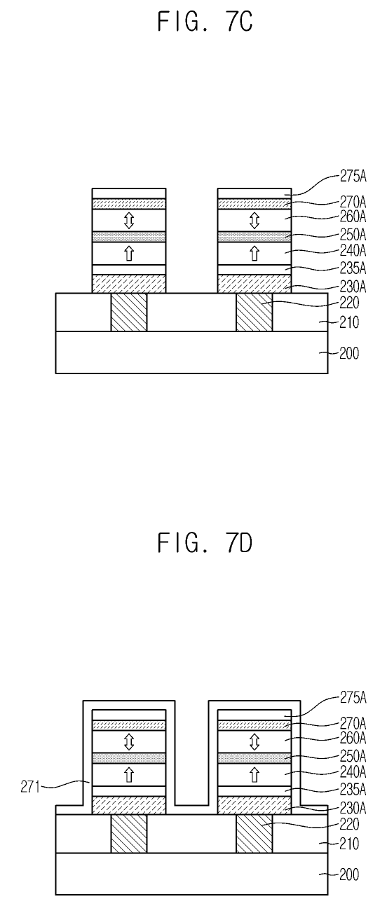

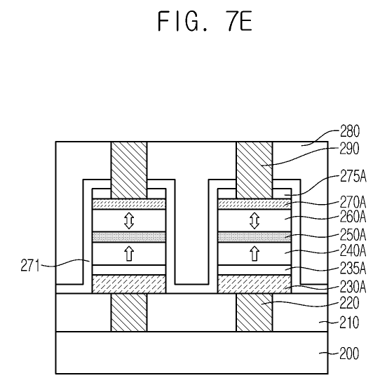

FIGS. 7A-7E are cross-sectional views illustrating a semiconductor device and a method for fabricating the same in accordance with another embodiment of the present invention. FIG. 7E shows a semiconductor device in accordance with the embodiment of the present disclosure, and FIGS. 7A-7E show intermediate process steps for fabricating the semiconductor device of FIG. 7E in accordance with the embodiment of the present disclosure.

First, the method for fabricating the semiconductor device will be described.

Referring to FIG. 7A, first, a substrate 200 may be provided, and a first inter-layer dielectric layer 210 may be formed over the substrate 200. The first inter-layer dielectric layer 210 may be a single layer or a multi-layer. For example, the first inter-layer dielectric layer 210 may include silicon oxide, silicon nitride, silicon oxynitride, and/or a low-k material.

After the first inter-layer dielectric layer 210 is formed, an etching process may be performed to form a contact hole penetrating the first inter-layer dielectric layer 210 and remove a portion of the first inter-layer dielectric layer 210. The etching process may be performed as a dry etching process using a plasma gas such as trifluoromethane (CHF₃), tetrafluoromethane (CF₄), or sulfur hexafluoride (SF₆), or a plasma gas such as CF₄/O₂ or CH₄/H₂, or as a wet etching process using hydrofluoric acid (HF) or a buffered oxide etchant (BOE).

Subsequently, for example, a metal deposition process may be used to fill the inside of a contact hole with a metal, and Chemical Mechanical Planarization (CMP) may be performed. As a material for a first electrode contact 220, a metal with excellent electrical properties may be used, and for example, tungsten (W), titanium (Ti), titanium nitride (TiN), tantalum (Ta), and tantalum nitride (TaN) may be used.

Referring to FIG. 7B, a first electrode layer 230, a seed layer 235, a fixed layer 240, a tunnel barrier layer 250, a free layer 260, a second electrode layer 270, and a second capping layer 275 may be formed over the planarized first inter-layer dielectric layer 210 and the first electrode contact 220. The first electrode layer 230, the seed layer 235, the fixed layer 240, the tunnel barrier layer 250, the free layer 260, the second electrode layer 270, and the second capping layer 275 may form an MTJ layer.

Subsequently, a hard mask layer 295 of a pillar shape for patterning the MTJ layer may be formed over the second capping layer 275. The MTJ layer may be patterned by using the hard mask layer 295 as an etching barrier to form an MTJ pattern. The hard mask layer 295 may be formed of a dielectric material such as silicon nitride or silicon oxynitride. The hard mask layer 295 may include, for example, at least one among carbon (C), silicon (Si), copper (Cu), tungsten (W), titanium (Ti), tantalum (Ta), aluminum (Al), and nitrides, oxides and borides including these elements, and metal nitrides, such as titanium nitride and tantalum nitride. The hard mask layer 295 may function to prevent unnecessary damage that may occur in a subsequent process while maintaining the structural integrity of the MTJ layer, to uniformly form each layer, and to create a desired pattern. In particular, the hard mask layer 295 may be formed in a pillar shape, which enables selective etching of the MTJ layer in a subsequent process. With the pillar-shaped hard mask layer 295, the MTJ layer may be precisely patterned to form an MTJ pattern, which is an important factor for maximizing the performance of the MTJ device. In a subsequent process, the MTJ layers may be selectively etched according to different etching conditions. This etching process may be performed by a physical etching process, such as an ion beam etching (IBE) process, or a chemical etching process, such as a reactive ion etching (RIE) process.

The hard mask layer 295 may have an etching selectivity with respect to the MTJ layer, which makes it possible to precisely control the patterning of the MTJ layer. The hard mask layer 295 may be etched by an ion beam or inert ions including reactive ions. For example, the hard mask layer 295 may be etched by an IBE process or an RIE process, and in this process, the MTJ layer may be etched on both sides of the hard mask layer 295. When this process is performed, only the MTJ layer corresponding to the lower portion of the hard mask layer 295 may remain in a pillar shape, so that each layer of the MTJ device is formed in a desired pattern.

This etching process may be performed until the upper surface of the inter-layer dielectric layer 210 is exposed, and thus the disclosed embodiments may enable precise patterning of the MTJ layer. In this process, the hard mask layer 295 may selectively protect the MTJ layer and remove the non-structural portion of the MTJ layer in the subsequent process. As a result, the structure of each layer in the MTJ pattern may be accurately formed.

Referring to FIG. 7C, the MTJ pattern may appear in a form in which the patterns of each layer are sequentially stacked, and each pattern may form a multi-layer pattern including a first electrode layer pattern 230A, a seed layer pattern 235A, a fixed layer pattern 240A, a tunnel barrier layer pattern 250A, a free layer pattern 260A, a second electrode layer pattern 270A, and a second capping layer pattern 275A.

After the MTJ pattern is formed, a process of removing the remaining hard mask layer 295 may be performed. In order to protect the MTJ pattern from being damaged during the process of removing the hard mask layer 295, a selective etching process may be applied. Finally, a passivation layer may be formed or a subsequent process may be performed to protect the MTJ pattern and perform an additional process.

Referring to FIG. 7D, a first capping layer 271 may be formed over the process structure of FIG. 7C, that is, over the patterned MTJ pattern of a pillar shape. Here, the first capping layer 271 may be formed to cover all the upper surface and sidewalls of the MTJ pattern and include beryllium oxide (BeO) to effectively release the heat generated during the operation of the MTJ device.

The first capping layer 271 may be formed in various ways according to the process conditions. By way of particular example, the first capping layer 271 may be formed by at least one among an atomic layer deposition (ALD) process, a chemical vapor deposition (CVD) process, and a sputtering process.

In particular, when the ALD process is used, a uniformly mixed single mixed layer or a composition-controlled thin layer may be formed by selecting and alternately or repeatedly implanting one or more among zirconium oxide (ZrO₂), aluminum nitride (AlN), silicon carbide (SiC), boron nitride (BN), magnesium oxide (MgO), and zinc oxide (ZnO) precursors together with a beryllium oxide (BeO) precursor.

The first capping layer 271 may also be formed in a multi-layer structure. For example, a multi-layer capping structure that harmonizes the thermal conductivity, insulation property, and interface protection property may be realized by forming a beryllium oxide layer first to cover the upper surface and sidewalls of the MTJ pattern, and then additionally forming a dielectric material layer including at least one among an aluminum nitride layer (AlN) or silicon oxide, silicon carbide, boron nitride, and aluminum oxide over the beryllium oxide layer.

The first capping layer 271 may be formed to have a thickness of approximately 1 nm to 20 nm. In particular embodiments, the process may be controlled to form the thickness of the first capping layer 271 in a range of approximately 3 nm to 10 nm. Within this range, not only the heat release property but also the process stability such as device integration, uniform layer thickness, and suppression of the layer stress may be secured.

Therefore, the first capping layer 271 formed to completely cover the upper surface and sidewalls of the MTJ pattern as illustrated in FIG. 7D may have a single beryllium oxide (BeO) layer, a multi-layer structure, or a mixed layer structure. The forming process and the thickness range may encompass all the diverse technical concept and spirit of the present disclosure. In this way, the technical effects of the present disclosure, such as improving the thermal stability (Δ) of the free layer, suppressing deterioration of the critical switching current (I_{c}), and preventing a read operation from being interfered, may be stably realized.

According to one embodiment of the present disclosure, after the first capping layer 271 is formed, an annealing process may be additionally performed in a temperature range of approximately 300° C. to 600° C. This process may be a post-processing process for stabilizing the physical, chemical, and electrical properties of the first capping layer 271 and improving the interface quality of the entire MTJ structure. To be specific, through a process of applying heat at a temperature of approximately 300° C. to 600° C. for a predetermined time after the first capping layer 271 is formed, the physical stability and electrical properties of the first capping layer 271 may be further improved.

The annealing process may be a post-process for enhancing the properties of the beryllium oxide (BeO) or beryllium oxide (BeO)-based mixed layer or a multi-layer structure that is used as the first capping layer 271. The following effects may be obtained through this process. First, the first capping layer 271 itself may become more firm and uniformly arranged, and the quantity of fine defects or abnormal atomic arrangements that may exist inside may be decreased. As a result, the thermal conductivity may be improved and the protective function of the layer may also be enhanced.

By performing the annealing process, the adhesion between the MTJ pattern and the first capping layer 271 may be improved, and unnecessary diffusion or oxidation reaction that may occur at the interface may be suppressed. This may allow the magnetization direction of the free layer pattern 260A to be stably maintained and decrease the deterioration of the critical switching current (I_{c}), thereby reducing the possibility that a read operation is interfered.

Furthermore, the annealing process may help to secure heat resistance in the subsequent process. For example, when a relatively high-temperature process, such as a subsequent process for depositing a dielectric layer or a process for forming a metal interconnection, is followed, the first capping layer 271 that has already been stabilized through the annealing process may be less susceptible to the damage from the temperature changes.

For this reason, the temperature range of the annealing process may be set to approximately 300° C. to 600° C. in accordance with the embodiments of the present disclosure. At a temperature which is lower than approximately 300° C., it may be difficult to sufficiently obtain the effect of crystallization or interface stabilization, and at a temperature exceeding approximately 600° C., the properties of the core layer of the MTJ device, such as the tunnel barrier layer pattern 250A or the free layer pattern 260A, may be damaged.

Therefore, when an annealing process is additionally performed after the first capping layer 271 is formed, the thermal stability (Δ) and the critical switching current (I_{c}) of the MTJ structure may be further stabilized, and the durability and reliability of the entire device may be improved.

FIG. 7E is a cross-sectional view illustrating forming a second inter-layer dielectric layer 280 and a second electrode contact 290 over the structure illustrated in FIG. 7D.

Referring to FIG. 7E, the second inter-layer dielectric layer 280 may be deposited to cover the entire process structure of FIG. 7D. The second inter-layer dielectric layer 280 may be a dielectric layer for securing the electrical insulation property of the device and providing a planar surface for forming an upper interconnection, and generally, silicon oxide (SiO₂), silicon nitride (SiN), or a low-k material may be used.

Subsequently, the second inter-layer dielectric layer 280 may be etched to form a via (contact) hole. The via hole may be formed to penetrate the first capping layer 271 and the second capping layer pattern 275A to contact the upper surface of the second electrode layer pattern 270A disposed in the lower portion. Subsequently, the second electrode contact 290 may be formed by filling the inside of the via hole with a conductive metal, such as tungsten (W), copper (Cu), and the like.

Through this structure, the electrical connection between the upper interconnection and the second electrode layer pattern 270A of the MTJ may be stably secured, and at the same time, the thickness of the second inter-layer dielectric layer 280 may be secured and the electrical insulation may also be maintained.

The unidirectional arrow in the fixed layer pattern 140A may indicate that the magnetization direction of the fixed layer pattern 140A is fixed vertically. The bidirectional arrow in the free layer pattern 160A may indicate that the magnetization direction of the free layer pattern 160A may be magnetized parallel or antiparallel to the magnetization direction of the fixed layer pattern 140A.

As a result of the process described above, a semiconductor device as illustrated in FIG. 7E may be fabricated.

Referring back to FIG. 7E, a semiconductor device in accordance with an embodiment of the present disclosure may include the first inter-layer dielectric layer 210 formed over the substrate 200, the first electrode contact 220 formed to penetrate the first inter-layer dielectric layer 210, and an MTJ pattern formed over the first electrode contact 220.

The MTJ pattern may include the first electrode layer pattern 230A, the seed layer pattern 235A, the fixed layer pattern 240A, the tunnel barrier layer pattern 250A, the free layer pattern 260A, the second electrode layer pattern 270A, and the second capping layer pattern 275A that are sequentially formed from the bottom. The MTJ stacked structure may function as a variable resistance memory layer that controls the spin direction to determine the resistance state of a memory cell.

The first capping layer 271 formed to cover the upper surface and sidewalls of the MTJ pattern may include beryllium oxide (BeO) having a thermal conductivity of approximately 100 W/m·K to 300 W/m·K. Also, the first capping layer 271 may preferably have a thickness of approximately 1 nm to 20 nm and may secure sufficient heat release performance even with a thinner layer, while contributing to improving the integration degree of the MTJ structure and maintaining the interface stability.

Subsequently, the second inter-layer dielectric layer 280 may be formed to cover the MTJ pattern, and the second inter-layer dielectric layer 280 may provide planarization and insulation properties for forming an upper interconnection. Also, the second electrode contact 290 formed to penetrate the second inter-layer dielectric layer 280 may be formed to precisely penetrate the first capping layer pattern 275A and then to contact the upper surface of the second electrode layer pattern 270A to electrically connect the MTJ and the upper interconnection to each other.

According to the semiconductor device and the method for fabricating the same described above, it is possible to efficiently release the heat generated during an MTJ operation to the outside, increase the thermal stability of the free layer pattern 260A, and suppress a read operation from being interfered at the same time by applying a beryllium oxide layer having a high thermal conductivity as the first capping layer 271 that covers the upper surface and sidewalls of the MTJ pattern. By forming the first capping layer 271 to have a thickness of approximately 1 nm to 20 nm, the physical stability, thin layer uniformity, interface quality of the layer, and the like may be optimized, and the process compatibility with the subsequent process of forming an interconnection and a process for depositing an inter-layer dielectric layer may also be improved. As a result, the present disclosure may be able to provide an effective technical means that may significantly contribute to improving the operational reliability and life span of the MTJ-based variable resistance memory device.

According to the embodiment of the present disclosure, the heat generated during the operation of the MTJ device may be effectively released to the outside by applying beryllium oxide (BeO) having a high thermal conductivity as a capping layer of a magnetic tunnel junction (MTJ).

The release of the heat to the outside may prevent the thermal stability (Δ) of the MTJ from being deteriorated and suppress the decrease in the critical switching current (I_{c}), which allows the magnetization state of the free layer to be stably maintained, and as a result, effectively prevents the read disturb phenomenon that may cause magnetization reversal during a read operation.

Also, according to embodiments of the present disclosure, since it is possible to form not only a beryllium oxide (BeO) single layer but also a composite capping layer or multi-layer structure through a combination of beryllium oxide (BeO) with diverse materials, such as aluminum nitride (AlN), zirconium oxide (ZrO₂), silicon oxide (SiO₂) and the like, diverse physical properties, such as thermal conductivity, oxidation resistance and process compatibility and so forth, may be improved as well.

While the present disclosure has been described with respect to the specific embodiments, it will be apparent to those skilled in the art that various changes and modifications may be made without departing from the spirit and scope of the invention as defined in the following claims.

What is claimed is:

1. A semiconductor device, comprising:
a variable resistance memory layer, including:
a plurality of magnetic tunnel junction (MTJ) layers; and
a first capping layer, including beryllium oxide, formed covering an upper surface and sidewalls of the plurality of MTJ layers,
wherein each MTJ layer includes
a fixed layer having a fixed magnetization direction,
a free layer having a changeable magnetization direction, and
a tunnel barrier layer disposed between the fixed layer and the free layer.

2. The semiconductor device of claim 1, wherein the first capping layer includes amorphous beryllium oxide.

3. The semiconductor device of claim 1, wherein the first capping layer includes crystalline beryllium oxide.

4. The semiconductor device of claim 1, wherein the first capping layer has a multi-layer structure including beryllium oxide and aluminum nitride (AlN).

5. The semiconductor device of claim 1, wherein the first capping layer includes a single layer of a mixture including beryllium oxide and at least one selected from a group including zirconium oxide, aluminum nitride, silicon carbide, boron nitride, magnesium oxide, and zinc oxide.

6. The semiconductor device of claim 1, wherein the first capping layer has a multi-layer structure further including, in addition to beryllium oxide, at least one selected from a group including silicon oxide, silicon carbide, boron nitride, and aluminum oxide.

7. The semiconductor device of claim 1, wherein the first capping layer includes beryllium oxide having a thermal conductivity of 100 W/m·K to 300 W/m·K.

8. The semiconductor device of claim 1, wherein the first capping layer has a thickness of 1 nm to 20 nm.

9. The semiconductor device of claim 1, wherein the fixed layer, the tunnel barrier layer, and the free layer are sequentially stacked over a substrate.

10. The semiconductor device of claim 9, further comprising:
a seed layer contacting a lower surface of the fixed layer; and
a second capping layer covering an upper surface of the free layer.

11. The semiconductor device of claim 10, wherein the seed layer includes tantalum (Ta), platinum (Pt), ruthenium (Ru), or magnesium oxide (MgO), and
the second capping layer includes beryllium oxide.

12. The semiconductor device of claim 11, wherein the second capping layer further includes, in addition to beryllium oxide, at least one selected from a group including silicon oxide, silicon carbide, boron nitride, and aluminum oxide.

13. A method for fabricating a semiconductor device, comprising:
forming, over a substrate, a magnetic tunnel junction (MTJ) layer including a fixed layer having a fixed magnetization direction, a free layer having a changeable magnetization direction, and a tunnel barrier layer interposed between the fixed layer and the free layer;
forming an MTJ pattern by patterning the MTJ layer using a hard mask layer as an etching barrier; and
forming a first capping layer, including beryllium oxide, covering an upper surface and sidewalls of the MTJ pattern.

14. The method of claim 13, wherein the forming of the first capping layer includes
performing an atomic layer deposition (ALD) process, a chemical vapor deposition (CVD) process, or a sputtering process.

15. The method of claim 13, wherein the forming of the first capping layer includes:
forming a beryllium oxide layer covering the upper surface and sidewalls of the MTJ pattern; and
forming an aluminum nitride layer covering the beryllium oxide layer.

16. The method of claim 13, wherein the forming of the first capping layer includes:
repeatedly implanting one or more precursors selected from a group including zirconium oxide, aluminum nitride, silicon carbide, boron nitride, magnesium oxide, and zinc oxide together with a beryllium oxide precursor by performing an atomic layer deposition (ALD) process.

17. The method of claim 13, wherein the forming of the MTJ layer includes
sequentially stacking the fixed layer, the tunnel barrier layer, and the free layer over the substrate.

18. The method of claim 17, further comprising:
forming a seed layer including tantalum (Ta), platinum (Pt), ruthenium (Ru), or magnesium oxide (MgO) before stacking the fixed layer; and
forming a second capping layer including beryllium oxide after stacking the free layer.

19. The method of claim 13, wherein the forming of the first capping layer includes:
forming a beryllium oxide layer covering the upper surface and sidewalls of the MTJ pattern; and
forming a material layer, including at least one selected from a group including silicon oxide, silicon carbide, boron nitride, and aluminum oxide, covering the beryllium oxide layer.

20. The method of claim 13, wherein the forming of the first capping layer includes
forming the first capping layer having a thickness of 1 nm to 20 nm.

21. The method of claim 13, further comprising:
before the forming of the first capping layer,
forming a second capping layer, including beryllium oxide, covering the upper surface of the MTJ pattern.

22. The method of claim 21, wherein, in addition to beryllium oxide, the second capping layer further includes:
one or more selected from a group including silicon oxide, silicon carbide, boron nitride, and aluminum oxide.

23. The method of claim 13, further comprising:
after the forming of the first capping layer,
performing an annealing process on the first capping layer at a temperature of 300° C. to 600° C.
